(19) United States
(12) Patent Application Publication
(10) Pub. No.: US 2016/0268134 A1
(43) Pub. Date: Sep. 15, 2016

(54) METHOD FOR MANUFACTURING SEMICONDUCTOR DEVICE

(71) Applicant: KABUSHIKI KAISHA TOSHIBA, Tokyo (JP)

(72) Inventors: Yasuhiro ISOBE, Kanazawa Ishikawa (JP); Kunio TSUDA, Nonoichi Ishikawa (JP)

(21) Appl. No.: 14/840,926

(22) Filed: Aug. 31, 2015

(30) Foreign Application Priority Data
Mar. 9, 2015 (JP) 2015-045977

(51) Int. Cl. H01L 21/18; H01L 21/306; H01L 21/304; H01L 21/02; H01L 21/324

(52) U.S. Cl. CPC H01L 21/187; H01L 21/0254; H01L 21/02609; H01L 21/02598; H01L 21/02458; H01L 21/324; H01L 21/304; H01L 21/30612

(57) ABSTRACT

A method for manufacturing a semiconductor device includes forming, on a substrate, a first conductivity type nitride semiconductor layer in which gallium nitride is contained, wherein the exposed face of the first conductivity type nitride semiconductor layer has a (0001) face, forming, on a substrate, a second conductivity type nitride semiconductor layer in which gallium nitride is contained, wherein the exposed face of the first conductivity type nitride semiconductor layer has a (000-1) face, and bonding the first conductivity type nitride semiconductor layer and the second conductivity type nitride semiconductor layer together by heating in a state where the first conductivity type nitride semiconductor layer faces and contacts the second conductivity type nitride semiconductor layer.

### CROSS-REFERENCE TO RELATED APPLICATION

This application is based upon and claims the benefit of priority from Japanese Patent Application No. 2015-045977, filed Mar. 9, 2015, the entire contents of which are incorporated herein by reference.

### FIELD

Embodiments described herein relate generally to a method for manufacturing a semiconductor device, and particularly to a method for manufacturing a semiconductor device in which a nitride semiconductor is used.

### BACKGROUND

Some uses of nitride semiconductors include high frequency electronic devices and power devices, as well as light-emitting diodes (LEDs) that are semiconductor light-emitting elements in a display device, illumination device, and the like.

A semiconductor device in which a nitride semiconductor is used has a stacked structure in which, for example, a plurality of nitride semiconductor layers including p-type nitride semiconductor layers and n-type nitride semiconductor layers are stacked one over the other on a silicon substrate. This stacked structure is formed by epitaxial growth of the nitride semiconductor layers. When the p-type nitride semiconductor layer is formed, the semiconductor device is taken out of a reactor and is heated, for example, in order to activate p-type impurities with which the nitride semiconductor layer is doped. Accordingly, regrowing of a further epitaxial layer is required when an n-type nitride semiconductor layer is to be formed on the p-type nitride semiconductor layer. During the regrowing, the main face of the exposed nitride semiconductor layer may become contaminated, and a favorable p-n junction may not be obtained at the interface of the two layers.

### DESCRIPTION OF THE DRAWINGS

FIG. 1 is a flowchart illustrating a method for manufacturing a semiconductor device according to a first embodiment.

FIG. 2 is a diagram illustrating manufacturing of the semiconductor device according to the first embodiment.

FIG. 3 is a diagram illustrating manufacturing of the semiconductor device according to the first embodiment.

FIG. 4 is a diagram illustrating manufacturing of the semiconductor device according to the first embodiment.

FIG. 5 is a diagram illustrating manufacturing of the semiconductor device according to the first embodiment.

FIG. 6 is a flowchart illustrating a method for manufacturing a semiconductor device according to a second embodiment.

FIG. 7 is a diagram illustrating manufacturing of the semiconductor device according to the second embodiment.

FIG. 8 is a diagram illustrating manufacturing of the semiconductor device according to the second embodiment.

FIG. 9 is a diagram illustrating manufacturing of the semiconductor device according to the second embodiment.

FIG. 10 is a diagram illustrating manufacturing of the semiconductor device according to the second embodiment.

FIG. 11 is a diagram illustrating manufacturing of the semiconductor device according to the second embodiment.

FIG. 12 is a diagram illustrating manufacturing of the semiconductor device according to the second embodiment.

FIG. 13 is a cross-sectional view of a semiconductor device according to a third embodiment.

FIG. 14 is a cross-sectional view of the semiconductor device according to the third embodiment.

### DETAILED DESCRIPTION

One embodiment provides a method for manufacturing a semiconductor device that enables forming of two nitride semiconductor layers of different conductivity types which have a favorable junction and favorable junction characteristics.

In general, according to one embodiment, a method for manufacturing a semiconductor device includes: forming, on a first substrate, a first conductivity type first nitride semiconductor layer containing gallium nitride, wherein the main face of the first nitride semiconductor layer on a side thereof opposite to the first substrate has a (0001) face, forming, on a second substrate, a second conductivity type second nitride semiconductor layer containing gallium nitride, and a main face of the second nitride semiconductor layer on a side thereof opposite to the second substrate has a (000-1) face, and bonding the first nitride semiconductor layer and the second nitride semiconductor together by heating them in a state where the first nitride semiconductor layer faces and is located against the second nitride semiconductor layer.

Embodiments will be described hereinafter with reference to the drawings. Since the drawings are schematically or conceptually illustrated, dimensions and proportions in each drawing may not necessarily be the same as the dimensions and proportions of an actual device. One or more embodiments described below merely illustrate devices and methods in order to implement the technical idea of the invention. Therefore, the technical idea of the invention is not specified by the shape, the structure, and the disposition of components in the embodiments. In the description below, configurations having the same function and configuration are given the same reference sign, and a duplicate description will be provided for those configurations only when necessary.

### First Embodiment

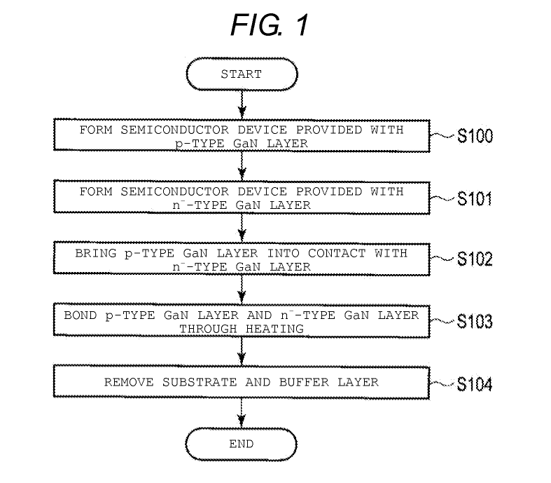

A description will be provided for a method of manufacturing a semiconductor device 1 according to a first embodiment with reference to the drawings. FIG. 1 is a flowchart illustrating the method of manufacturing the semiconductor device 1 according to the first embodiment. In the present embodiment, deposition forming of the nitride semiconductor layers is performed by epitaxial growth using, for example, metal organic chemical vapor deposition (MOCVD).

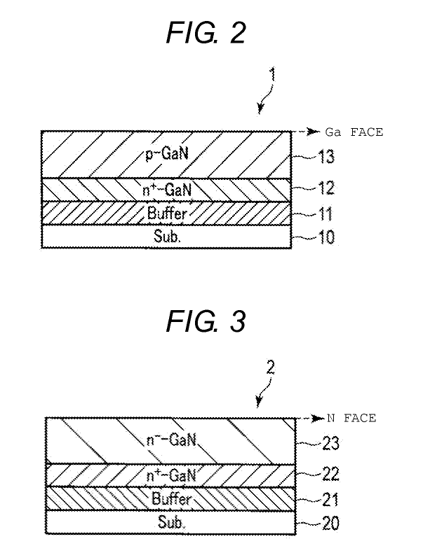

A semiconductor device 1 provided with a p-type nitride semiconductor layer 13 as the uppermost layer on a substrate is formed as illustrated in FIG. 2 (step S100). The semiconductor device 1 is provided with a substrate (sub.) 10. The substrate 10 is, for example, a silicon (Si) substrate. As the substrate 10, for example, sapphire (Al₂O₃), silicon carbide (SiC), gallium phosphide (GaP), indium phosphide (InP), gallium arsenide (GaAs), or gallium nitride (GaN) having a (0001) face may also be used. The substrate 10 is not limited to the above-described ones. The substrate 10 is preferably a monocrystalline substrate on which an epitaxial layer can be grown.

Next, a buffer layer 11 is formed on the substrate 10 using MOCVD. The buffer layer 11 includes a nitride semiconductor and the like. For example, the buffer layer 11 is formed of aluminum nitride (AlN). The buffer layer has the functions of alleviating strain that is caused by the difference in lattice constant between a nitride semiconductor layer formed on the buffer layer and the substrate and of controlling the crystallinity of the nitride semiconductor layer formed on the buffer layer. The buffer layer also has a function of suppressing a chemical reaction between the elements (for example, gallium (Ga)) that are contained in the nitride semiconductor layer formed on the buffer layer and the elements (for example, silicon (Si)) in the substrate. The buffer layer 11 may not need to be provided depending on the composition of the substrate used.

Next, an n⁺-type nitride semiconductor layer 12 doped with a high-concentration n-type dopant is formed on the buffer layer 11 using MOCVD. The nitride semiconductor layer 12 is formed of, for example, gallium nitride (GaN). Silicon (Si), for example, is used as the n-type dopant.

Next, a nitride semiconductor layer 13 doped with a p-type dopant is formed on the n⁺-type GaN layer 12 by using MOCVD. The nitride semiconductor layer 13 is formed of, for example, GaN. Magnesium (Mg), for example, is used as the p-type dopant.

GaN has the crystal structure of a hexagonal crystal system. Since it has lattice polarities in the c-axis direction, GaN has two c faces consisting of a (0001) face and a (000-1) face. The (0001) face and the (000-1) face may be referred respectively to as a +c face and a −c face. The (0001) face of GaN is a gallium face (Ga face) in which gallium atoms are disposed. The (000-1) face of GaN is a nitrogen face (N face) in which nitrogen atoms are disposed. In the present embodiment, the GaN layer 13 is formed so that the main face, i.e., the face not facing the underlying substrate, of the GaN layer 13 is the Ga face. The crystalline structure of the GaN layer 13 is controlled by the n⁺-type GaN layer 12 below the GaN layer 13 (or a layer further below). The n⁺-type GaN layer 12 is formed so that the main face of the n⁺-type GaN layer 12 is the Ga face. Accordingly, the GaN layer 13 that is grown on the n⁺-type GaN layer 12 is formed so that the main face of the GaN layer 13 is the Ga face.

Next, the semiconductor device 1 is heated, for example, at 500° C. for five minutes in a nitrogen atmosphere, and the p-type impurity in the GaN layer 13 is activated. Accordingly, the p-type GaN layer 13 is formed. The dopant concentration (or the carrier concentration) in the p-type GaN layer 13 can be arbitrarily set based on the quantity of p-type dopants incorporated therein during deposition of the layer.

Next, a semiconductor device 2 provided with an n⁻-type nitride semiconductor layer 23 in the uppermost layer is formed as illustrated in FIG. 3 (step S101). The step S100 of forming the semiconductor device 1 and the step S101 of forming the semiconductor device 2 may be reversed in FIG. 1. The semiconductor device 2 is provided with a substrate 20 and a buffer layer 21 disposed on the substrate 20. The substrate 20 is, for example, a free standing gallium nitride (GaN) substrate having the (000-1) face as the main face, an off-angled sapphire (Al₂O₃) substrate, an off-angled silicon (Si) substrate, or a silicon carbide (SiC) substrate having the c face as the main face. The buffer layer 21 includes a nitride semiconductor and the like. For example, the buffer layer 21 is formed of aluminum nitride (AlN).

Next, an n⁺-type nitride semiconductor layer 22 doped with a high-concentration n-type impurity is formed on the buffer layer 21 using MOCVD. The nitride semiconductor layer 22 is formed of, for example, GaN.

Next, the n⁻-type nitride semiconductor layer 23 doped with a low-concentration n-type impurity is formed on the n⁺-type GaN layer 22 using MOCVD. The nitride semiconductor layer 23 is formed of, for example, GaN. A GaN layer is n⁻-type when epitaxially grown in an undoped state, i.e., without the purposeful addition of dopant additives. Thus, the nitride semiconductor layer 23 may not be intentionally doped with an n-type impurity when a GaN layer is used as the nitride semiconductor layer 23. The impurity concentration in the GaN layer 23 may be adjusted by doping the GaN layer 23 with an n-type impurity. The undoped state means that a semiconductor is not intentionally doped with impurities. A layer having an amount of unintentionally incorporated impurities that may be introduced during, for example, manufacturing, is considered to be in the undoped state.

The GaN layer 23 is formed so that the main face (top face) of the GaN layer 23 is the N face. The crystal structure of the GaN layer 23 is controlled by the n⁺-type GaN layer 22 below the GaN layer 23 (or a layer further below). The n⁺-type GaN layer 22 is formed so that the main face of the n⁺-type GaN layer 22 is the N face. Accordingly, the n⁻-type GaN layer 23 that is grown on the n⁺-type GaN layer 22 is formed so that the main face of the n⁻-type GaN layer 23 is the N face.

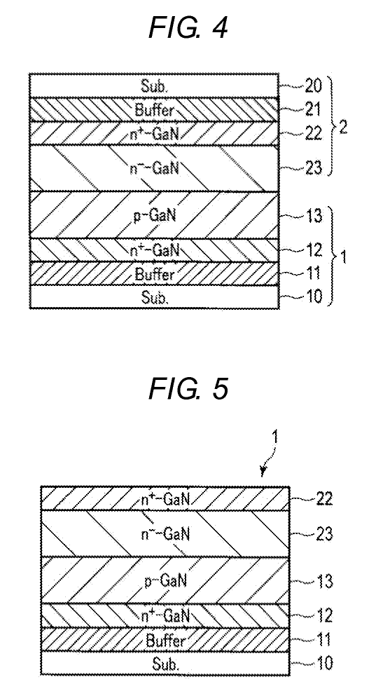

Next, as illustrated in FIG. 4, the semiconductor device 1 and the semiconductor device 2 are positioned so that the p-type GaN layer 13 faces the n⁻-type GaN layer 23, and the p-type GaN layer 13 is brought into contact with the n⁻-type GaN layer 23, or vice-versa (step S102). Accordingly, the Ga face of the p-type GaN layer 13 comes into contact with the N face of the n⁻-type GaN layer 23.

Next, the p-type GaN layer 13 and the n⁻-type GaN layer 23 are bonded together, for example, by heating the stacked structure at 500° C. for 60 minutes (step S103). Since the main face of the p-type GaN layer 13 is the Ga face, and the main face of the n⁻-type GaN layer 23 is the N face, a favorable junction is obtained at the interface between the p-type GaN layer 13 and the n⁻-type GaN layer 23 because GaN can form at the junction. The bonding is desirably performed in a vacuum state. Accordingly, discontinuities in the interface between the p-type GaN layer 13 and the n⁻-type GaN layer 23 can be reduced, and thus a favorable junction obtained. The top face of the p-type GaN layer 13 and the top face of the n⁻-type GaN layer 23 are desirably cleaned before the bonding. Accordingly, impurities included in the interface between the p-type GaN layer 13 and the n⁻-type GaN layer 23 can be reduced.

Next, the substrate 20 and the buffer layer 21 are removed as illustrated in FIG. 5 (step S104). Dry etching including reactive ion etching (RIE), for example, is used to remove the substrate 20 and the buffer layer 21. Accordingly, a stacked structure of a p-type GaN layer 13 and an n⁻-type GaN layer can be formed on one substrate 10. In FIG. 5, the semiconductor device from which the one substrate 20 is removed is represented as the semiconductor device 1. Alternatively, the substrate 10 and buffer layer 10 may be removed.

The configuration of the plurality of nitride semiconductor layers with which the semiconductor device 1 is provided is set depending on the types of the finally manufactured semiconductor element. For example, when an n⁺-type GaN layer 22 on the n⁻-type GaN layer 23 is not necessary, the n⁺-type GaN layer 22 is not formed, and the n⁻-type GaN layer 23 is formed on the buffer layer 21 in the step S101. As such, the configuration of the plurality of nitride semiconductor layers with which the semiconductor device 1 is provided can be arbitrarily designed.

Effect

In the first embodiment, as described above in detail, the semiconductor device 1 provided with the p-type nitride semiconductor layer (p-type GaN layer) 13 in the uppermost layer and the semiconductor device 2 provided with the n⁻-type nitride semiconductor layer (n⁻-type GaN layer) 23 in the uppermost layer are formed. The p-type GaN layer 13 is formed so that the main face of the p-type GaN layer 13 is the Ga face. The n⁻-type GaN layer 23 is formed so that the main face of the n⁻-type GaN layer 23 is the N face. The p-type GaN layer 13 and the n⁻-type GaN layer 23 are bonded together by heating while the p-type GaN layer 13 faces and contacts the n⁻-type GaN layer 23.

According to the first embodiment, since the Ga face of the p-type GaN layer 13 comes in contact with the N face of the n⁻-type GaN layer 23, the p-type GaN layer 13 and the n⁻-type GaN layer 23 can be bonded together. In addition, since the Ga face of the p-type GaN layer 13 and the N face of the n⁻-type GaN layer 23 are bonded together, a stacked structure of the p-type GaN layer 13 and the n⁻-type GaN layer 23 having a favorable junction surface can be formed.

The stacked structure of the p-type GaN layer 13 and the n⁻-type GaN layer 23 can be formed through bonding. In addition, a p-type GaN layer as an intermediate layer can be formed within the plurality of stacked nitride semiconductor layers.

The p-type dopant included in the p-type GaN layer 13 can be activated through, for example, heating before bonding. Accordingly, a p-type GaN layer 13 having favorable characteristics can be formed. When an n-type GaN layer is present on a GaN layer that is doped with a p-type impurity (for example, magnesium (Mg)), dehydrogenation of the Mg doped GaN does not proceed, and the GaN layer may not be p-type. In addition, controlling the impurity profile in the stacked structure is difficult because magnesium (Mg) as a dopant is likely to be diffused and segregated during crystal growth. However, in the present embodiment, such a problem can be avoided.

In general, when an n⁻-type GaN layer is formed on a p-type GaN layer through epitaxial growth after an anneal or heating step, or after exposure of the substrate to an environment outside of the epitaxial growth chamber, the junction surface is contaminated by impurities such as silicon (Si), oxygen, and carbon, and a favorable junction is not obtained. Meanwhile, in the present embodiment, a p-n junction between a p-type GaN layer and an n⁻-type GaN layer can be formed without the need for epitaxial growth following the anneal or heating step. The amount of impurities in the interface between the p-type GaN layer 13 and the n⁻-type GaN layer 23 can be further reduced by bonding the p-type GaN layer 13 and the n⁻-type GaN layer 23 in a vacuum state after the top faces of the p-type GaN layer 13 and the n⁻-type GaN layer 23 are cleaned. Accordingly, a favorable p-n junction can be formed.

### Second Embodiment

A semiconductor device 1 provided with the p-type nitride semiconductor layer 13 partially disposed on the n⁺-type nitride semiconductor layer 12 and a semiconductor device 2 provided with the n⁻-type nitride semiconductor layer 23 partially disposed on the n⁺-type nitride semiconductor layer 22 are formed in a second embodiment. Then, a face of the p-type nitride semiconductor layer 13 is brought into contact with a face of the n⁻-type nitride semiconductor layer 23, and the p-type nitride semiconductor layer 13 and the n⁻-type nitride semiconductor layer 23 are bonded together in the in-plane direction.

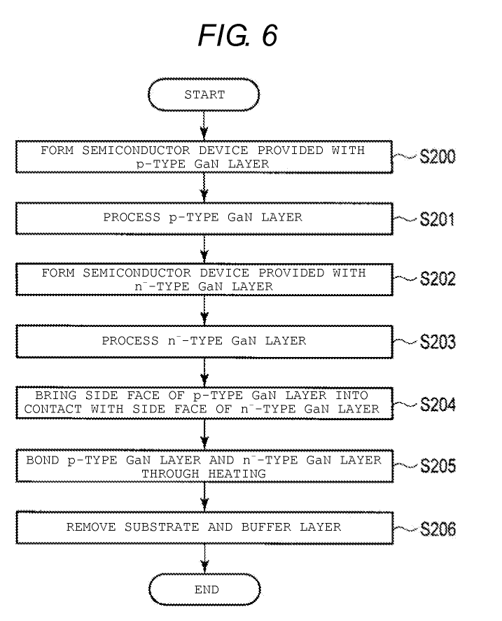

A description will be provided for a method for manufacturing the semiconductor device 1 according to the second embodiment with reference to the drawings. FIG. 6 is a flowchart illustrating the method for manufacturing the semiconductor device 1 according to the second embodiment.

The semiconductor device 1 provided with the p-type GaN layer 13 in the uppermost layer is formed in the same manner as the first embodiment (step S200). The p-type GaN layer 13 is formed so that the main face of the p-type GaN layer 13 is the Ga face. The n⁺-type GaN layer 12 is also formed so that the main face of the n⁺-type GaN layer 12 is the Ga face.

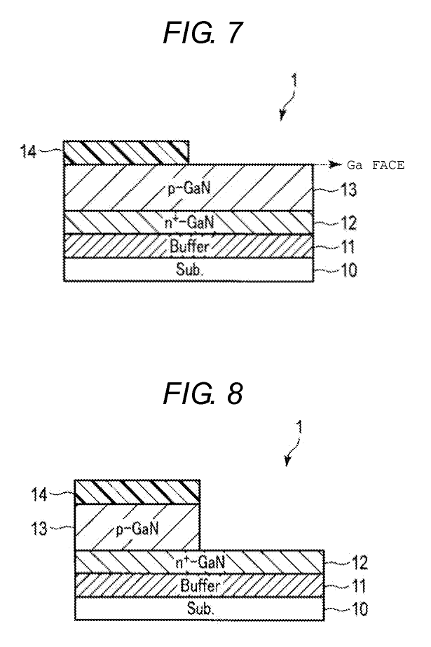

Next, the p-type GaN layer 13 is processed (step S201). That is to say, a resist layer (patterned mask layer) 14 that partially covers the main face of the p-type GaN layer 13 is formed by photolithography as illustrated in FIG. 7. Next, the p-type GaN layer 13 is etched using the resist layer 14 as a mask as illustrated in FIG. 8. Reactive ion etching (RIE), for example, is used in the etching. The resist layer 14 is removed afterward.

Next, the semiconductor device 2 provided with the n⁻-type GaN layer 23 in the uppermost layer is formed in the same manner as the first embodiment (step S202). The n⁻-type GaN layer 23 is formed so that the main face of the n⁻-type GaN layer 23 is the N face. The n⁺-type GaN layer 22 is also formed so that the main face of the n⁺-type GaN layer 22 is the N face. Furthermore, the thickness of the n⁻-type GaN layer 23 is set to be approximately the same as the thickness of the p-type GaN layer 13.

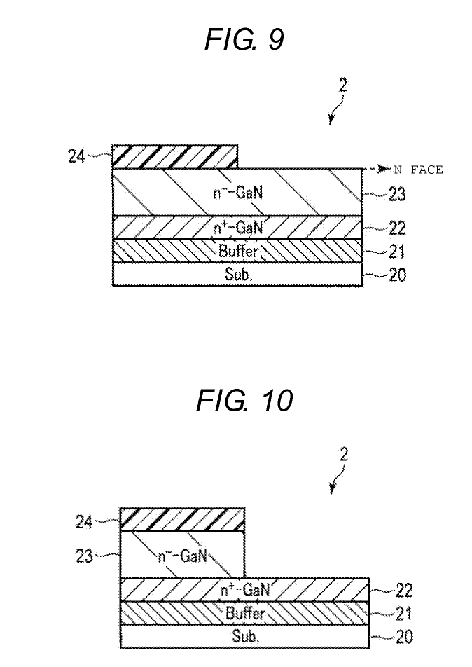

Next, the n⁻-type GaN layer 23 is processed (step S203). That is to say, a resist layer (patterned mask layer) 24 that covers a partial area of the main face of the n⁻-type GaN layer 23 is formed by photolithography as illustrated in FIG. 9. Next, the n⁻-type GaN layer 23 is etched with the resist layer 24 used as a mask as illustrated in FIG. 10. RIE, for example, is used in the etching. The resist layer 24 is removed afterward.

When the p-type GaN layer 13 is processed in order to remain at the left on the n⁺-type GaN layer 12 as illustrated in FIG. 8, the n⁻-type GaN layer 23 is correspondingly processed in order to remain at the left on the n⁺-type GaN layer 22. The steps S200 and S201 of forming the semiconductor device 1 and the steps S202 and S203 of forming the semiconductor device 2 may be reversed in FIG. 6.

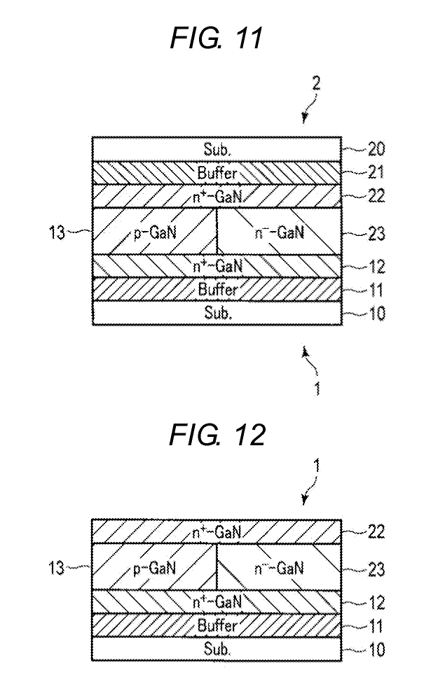

Next, the side face of the p-type GaN layer 13 is brought into contact with the side face of the n⁻-type GaN layer 23 as illustrated in FIG. 11 (step S204). The Ga main face of the p-type GaN layer 13 thus comes in contact with the N main face of the n⁺-type GaN layer 22, and the N main face of the n⁻-type GaN layer 23 thus comes in contact with the Ga main face of the n⁺-type GaN layer 12.

Next, the side face of the p-type GaN layer 13 and the side face of the n⁻-type GaN layer 23 are bonded together by heating (step S205), and the main surfaces of the n⁻-type GaN layer 23 and the n⁺-type GaN layer 22, as well as the n⁺-type GaN layer 22 and the p-type GaN layer 13, are bonded together. Since the p-type GaN layer 13 the Ga face of which is grown and the n⁻-type GaN layer 23 the N face of which is grown are bonded together in the in-plane direction at this time, a favorable junction surface is obtained in the interface between the p-type GaN layer 13 and the n⁻-type GaN layer 23. In addition, since the main face of the p-type GaN layer 13 is the Ga face, and the main face of the n⁺-type GaN layer 22 is the N face, a favorable junction surface is obtained in the interface between the p-type GaN layer 13 and the n⁺-type GaN layer 22. Similarly, since the main face of the n⁻-type GaN layer 23 is the N face, and the main face of the n⁺-type GaN layer 12 is the Ga face, a favorable junction surface is obtained in the interface between the n⁻-type GaN layer 23 and the n⁺-type GaN layer 12.

Next, the substrate 20 and the buffer layer 21 are removed as illustrated in FIG. 12 (step S206). Dry etching including RIE, for example, is used in the removing. Accordingly, a p-type GaN layer 13 and the n⁻-type GaN layer 23 that are bonded together in the in-plane direction of the main surface of an underlying substrate 10 can be formed on one substrate 10. In FIG. 12, the semiconductor device from which the substrate 20 was removed is represented as the semiconductor device 1.

Effect

According to the second embodiment, as described above in detail, the side face of the p-type GaN layer 13 and the side face of the n⁻-type GaN layer 23 can be bonded together through bonding. In addition, the n⁺-type GaN layer 22 can be formed on the p-type GaN layer 13. Other effects are the same as the effects of the first embodiment.

The configuration in FIG. 12 is merely an example. Forming a semiconductor device in which a plurality of p-n junctions are repeated in the in-plane direction of the main surface of a substrate is also possible by applying the manufacturing method in the second embodiment.

### Third Embodiment

In a third embodiment, a description will be provided for a configuration example of the semiconductor device in which the p-n junction that is formed according to the first and the second embodiments is used. Two examples (first and second examples) will be described hereinafter.

### First Example

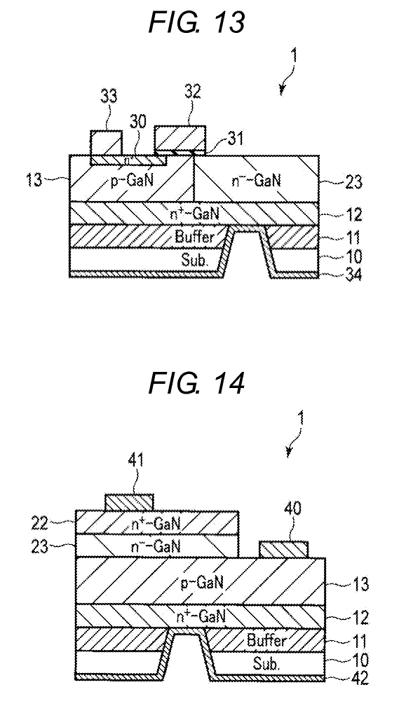

A first example is a configuration example of a vertical power metal oxide semiconductor field-effect transistor (MOSFET) that is the semiconductor device to which the p-n junction in the second embodiment is applied. FIG. 13 is a cross-sectional view of the semiconductor device (vertical power MOSFET) 1 according to the first example. FIG. 13 illustrates an example of an n-channel MOSFET.

The semiconductor device 1 is provided with the substrate 10, the buffer layer 11, the n⁺-type drain layer 12, the p-type base layer 13, the n⁻-type drift layer 23, an n⁺-type source region 30, a gate insulating film 31, a gate electrode 32, a source electrode 33, and a drain electrode 34.

The drain layer 12 is disposed on the buffer layer 11. The drain layer 12 is an n⁺-type nitride semiconductor layer. In the present example, the drain layer 12 is an n⁺-type GaN layer. The drain layer 12 is electrically connected to the drain electrode 34. The drain electrode 34 is disposed on the bottom face of the substrate 10 and comes in contact with the drain layer 12 through an opening portion that is disposed through the substrate 10 and the buffer layer 11.

The base layer 13 and the drift layer 23 are disposed on the drain layer 12. The base layer 13 and the drift layer 23 are bonded together in the in-plane direction in the same manner as the second embodiment. The base layer 13 is a p-type nitride semiconductor layer. In the present example, the base layer 13 is a p-type GaN layer. The drift layer 23 is an n⁻-type nitride semiconductor layer. In the present working example, the drift layer 23 is an n⁻-type GaN layer.

The source region 30 is disposed in the base layer 13 and includes an n⁺-type semiconductor region. The source region 30 is formed by implanting ions of an n-type impurity into the base layer 13. The source electrode 33 is disposed on the source region 30.

The gate insulating film 31 is disposed on the base layer 13 in order to be in contact with the source region 30 and the drift layer. The gate electrode is disposed on the gate insulating film 31.

The semiconductor device (vertical power MOSFET) 1 according to the first example is configured as above.

### Second Example

A second example is a configuration example of a bipolar transistor that is the semiconductor device to which the p-n junction in the first embodiment is applied. FIG. 14 is a cross-sectional view of the semiconductor device (bipolar transistor) 1 according to the second example. FIG. 14 illustrates an example of an npn-type bipolar transistor.

The semiconductor device 1 is provided with the substrate 10, the buffer layer 11, the n⁺-type collector layer 12, the p-type base layer 13, the n⁻-type emitter layer 23, the n⁺-type contact layer 22, a base electrode 40, an emitter electrode 41, and a collector electrode 42.

The collector layer 12 is disposed on the buffer layer 11. The collector layer 12 is an n⁺-type nitride semiconductor layer. In the present example, the collector layer 12 is an n⁺-type GaN layer. The collector layer 12 is electrically connected to the collector electrode 42. The collector electrode 42 is disposed on the bottom face of the substrate 10 and comes in contact with the collector layer 12 through an opening portion that is disposed in the substrate 10 and the buffer layer 11.

The base layer 13 is disposed on the collector layer 12. The base layer 13 is a p-type nitride semiconductor layer. In the present example, the base layer 13 is a p-type GaN layer.

The emitter layer 23 and the base electrode 40 are disposed on the base layer 13 at an interval therebetween. The emitter layer 23 is an n⁻-type nitride semiconductor layer. In the present example, the emitter layer 23 is an n⁻-type GaN layer.

The contact layer 22 is disposed on the emitter layer 23. The contact layer 22 is an n⁺-type nitride semiconductor layer. In the present example, the contact layer 22 is an n⁺-type GaN layer. The emitter electrode 41 is disposed on the contact layer 22.

The semiconductor device (bipolar transistor) 1 according to the second example is configured as above.

According to the third embodiment, as described in detail so far, various semiconductor devices can be configured by using the p-n junction that is described in the first and the second embodiments. In addition to the semiconductor devices illustrated in the third embodiment, various semiconductor devices can be configured by applying the p-n junction that is described in the first and the second embodiments.

In each embodiment above, a p-type GaN layer the Ga face of which is exposed as the main face and an n⁻-type GaN layer the N face of which is exposed as the main face are bonded together. However, not limited to this configuration, an n⁻-type GaN layer the Ga face of which is exposed as the main face and a p-type GaN layer the N face of which is exposed as the main face may be bonded together.

While MOCVD is used for depositing in each embodiment above, depositing is not limited to MOCVD. Other deposition methods such as molecular beam epitaxy (MBE) may also be used.

In the present specification, the term “nitride semiconductor” includes semiconductors having all possible compositions obtained from a chemical formula InₓAl_{y}Ga_{(1-x-y)}N (where 0≦x<1, 0≦y<1, and 0≦x+y<1) by changing the composition ratio of x and y within each range thereof. The term “nitride semiconductor” also includes semiconductors that further include Group V elements other than nitrogen (N), semiconductors that further include various elements which are added in order to control various characteristics such as a conductivity type, and semiconductors that further include various elements which are contained unintentionally in the above chemical formula.

In the present specification, the expression “stacked layers” includes, in addition to a case where layers are stacked in contact with each other, a case where layers are stacked while other layers are inserted between the layers. In addition, the expression “disposed on” includes, in addition to a case where one layer is disposed on another in direct contact, a case where one layer is disposed on another while other layers are inserted between the layers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device comprising:
forming, on a first substrate, a first conductivity type first nitride semiconductor layer comprising gallium nitride, a main face thereof that is on a side opposite to the first substrate, having a (0001) face;
forming, on a second substrate, a second conductivity type second nitride semiconductor layer comprising gallium nitride, a main face thereof that is on a side opposite to the second substrate, having a (000-1) face; and
bonding together the first nitride semiconductor layer and the second nitride semiconductor by heating in a state where the first nitride semiconductor layer faces the second nitride semiconductor layer.

2. The method according to claim 1, further comprising:
forming, between the first substrate and the first nitride semiconductor layer, a third nitride semiconductor layer comprising gallium nitride, a main face thereof that is on a side of the first nitride semiconductor layer, having a (0001) face; and
forming, between the second substrate and the second nitride semiconductor layer, a fourth nitride semiconductor layer comprising gallium nitride, a main face thereof that is on a side of the second nitride semiconductor layer, having a (000-1) face.

3. The method according to claim 2, wherein the third and the fourth nitride semiconductor layers are both of the second conductivity type.

4. The method according to claim 3, wherein the third and the fourth nitride semiconductor layers each have a dopant concentration higher than a dopant concentration of the second nitride semiconductor layer.

5. The method according to claim 1, wherein the first and the second nitride semiconductor layers comprise InₓAl_{y}Ga_{(1-x-y)}N (where 0≦x<1, 0≦y<1, and 0≦x+y<1).

6. The method according to claim 1, further comprising:
heating the first nitride semiconductor layer to a temperature sufficient to activate dopants therein prior to bonding together the first nitride semiconductor layer and the second nitride semiconductor layer.

7. The method of claim 6, wherein the heating of the first nitride semiconductor layer prior to bonding together the first nitride semiconductor layer and the second nitride semiconductor layer is performed in vacuum.

8. The method according to claim 1, further comprising:
removing the second substrate after bonding together the first nitride semiconductor layer and the second nitride semiconductor layer.

9. The method according to claim 8, wherein the second substrate is removed by wet etching or grinding.

10. A method for manufacturing a semiconductor device comprising:
forming, on a first substrate, a first nitride semiconductor layer comprising gallium nitride, wherein the main face thereof on the side opposite to the first substrate has a (0001) face;
forming, on the first nitride semiconductor layer, a first conductivity type second nitride semiconductor layer comprising gallium nitride, wherein the main face thereof on a side opposite to the first nitride semiconductor layer has a (0001) face;
etching a portion of the second nitride semiconductor layer to form a side face extending thereinto;
forming, on a second substrate, a third nitride semiconductor layer comprising gallium nitride, wherein the main face thereof on the side opposite to the second substrate has a (000-1) face;
forming, on the third nitride semiconductor layer, a second conductivity type fourth nitride semiconductor layer comprising gallium nitride, wherein the main face thereof on the side opposite to the third nitride semiconductor layer has a (000-1) face;
etching a portion of the fourth nitride semiconductor layer to form a side face extending thereinto; and
bonding together the second nitride semiconductor layer and the fourth nitride semiconductor layer by heating them in a state where a side face of the second nitride semiconductor layer comes into contact with aside face of the fourth nitride semiconductor layer during the heating.

11. The method according to claim 10, wherein the first and the third nitride semiconductor layers are the second conductivity type.

12. The method according to claim 11, wherein the first and the third nitride semiconductor layers have a dopant concentration higher than a dopant concentration of the fourth nitride semiconductor layer.

13. The method according to claim 10, wherein the second and the fourth nitride semiconductor layers contain InₓAl_{y}Ga_{(1-x-y)}N (where 0≦x<1, 0≦y<1, and 0≦x+y<1).

14. The method according to claim 10, further comprising:
removing the second substrate after bonding together the second nitride semiconductor layer and the fourth nitride semiconductor layer.

15. The method according to claim 14, wherein the substrate is removed by wet etching or grinding.

16. A method of forming a gallium nitride semiconductor device, comprising:
forming, on a first substrate, a p-type monocrystalline gallium nitride layer having Ga at the exposed face of the crystalline structure thereof;
forming, on a second substrate, an n-type monocrystalline gallium nitride layer having N at the exposed face of the crystalline structure thereof;
positioning the p-type gallium nitride layer surface and the n-type gallium nitride layer surface in contact with one another; and
heating the p-type gallium nitride layer surface and the n-type gallium nitride layer surface in contact with one another and bonding together the p-type gallium nitride layer and the n-type gallium nitride layer at the interface of the p-type gallium nitride layer surface and the n-type gallium nitride layer surface in contact with one another.

17. The method of claim 16, wherein the n-type gallium nitride layer is an n⁻-type gallium nitride layer.

18. The method of claim 16, further comprising removing one of the first and the second substrates after bonding together the p-type gallium nitride layer and the n-type gallium nitride layer.

19. The method of claim 16, further comprising:
heating the p-type gallium nitride semiconductor layer to a temperature sufficient to activate dopants therein prior to bonding the p-type nitride semiconductor layer to the n-type gallium nitride semiconductor layer.

20. The method of claim 19, wherein the p-type nitride semiconductor layer and the n-type gallium nitride semiconductor layers are bonded together in vacuum.
